(19) United States
(12) Patent Application Publication
(10) Pub. No.: US 2005/0017376 A1
(43) Pub. Date: Jan. 27, 2005

(54) IC chip with improved pillar bumps

(75) Inventor: Chi-Long Tsai, Kaohsiung (TW)

Correspondence Address: TROXELL LAW OFFICE PLLC, SUITE 1404, 5205 LEESBURG PIKE, FALLS CHURCH, VA, 22041, US

(73) Assignee: Advanced Semiconductor Engineering Inc.

(21) Appl. No.: 10/896,910

(22) Filed: Jul. 23, 2004

(30) Foreign Application Priority Data
Jul. 23, 2003 (TW) 092120157

(51) Int. Cl. H01L 21/44

(52) U.S. Cl. 257/786

(57) ABSTRACT

An IC chip with a plurality of improved pillar bumps is disclosed. A chip has a plurality of bonding pads on its active surface. An Under Bump Metallurgy layer (UBM) is formed onto the bonding pads. A solder layer is formed over the UBM layer to connect the pillar bumps so that the pillar bumps will not contact the UBM layer. The solder layer has a melting point lower than that of the pillar bumps. The solder layer can connect the bottom surfaces of the pillar bumps through a reflowing process under shape retaining of the pillar bumps for improving the stress resistance and the bonding strength of the pillar bumps.

### FIELD OF THE INVENTION

The present invention relates to an integrated circuit, more particularly to an integrated circuit chip with improved pillar bumps.

### BACKGROUND OF THE INVENTION

In the conventional integrated circuit (IC) chip, wire-bonding is generally used to electrically connect the bonding pads of a chip to a substrate. However, flip-chip bonding and inner lead bonding gradually replace wire-bonding for the solutions of the recent integrated circuit (IC) development in smaller dimension, higher density and faster electrical response. It is necessary that bumps are formed on the active surface of an IC chip to bond to a substrate for flip-chip bonding and inner lead bonding applications. The bumps have various shapes to meet different requirements of manufacturing processes such as sphere, hemisphere, lump, and pillar. Normally spherical or hemispherical bumps are formed by low temperature solder paste which is heated to melt in a reflow furnace and then cooled down to form their shapes according to their surface tension. However, the pillar bumps dose not change their shape at the chip-bonding temperature so that there is no solder bridging issue. The pillar bumps are good candidates for IC chips in fine pitch bumping.

An IC chip with pillar bumps is disclosed in R.O.C. Taiwan Patent No. 517,370. Referring to FIG. 1, an IC chip 10 has a plurality of bonding pads 11 on its active surface. A passivation layer 12 is formed over the active surface of the chip 10 to partially expose the bonding pads. A plurality of pillar bumps are made from a first solder layer 21 containing a high percent of lead (Pb), and the pillar bumps are directly bonded to the bonding pads 11 and are partially covered by the passivation layer 12. The pillar bumps are fabricated at openings of a photoresist by electroplating technique (not shown in figure). A second solder layer 22 is further formed on the first solder layer 21 (pillar bumps). The second solder layer 22 is made from a solder paste containing low percent of lead (Pb) and has a lower melting point than that of the first solder layer 21. The second solder layer 22 is reflowed between 200 and 220° C. to form an arc surface, while the first solder layer 21 will maintain its pillar shape. Since the first solder layer 21 has a higher melting point between 320 and 360° C., the first solder layer 21 will always remain in pillar shape either during reflowing the second solder layer 22 or during chip-bonding processes. The bonding strength of the first solder layer 21 to the bonding pads 11 will be weakened resulting in crack 23 on the bottom of the first solder layer 21 due to metal fatigue. Though undisclosed, it is understood that an under bump metallurgy (UBM) layer can be formed between the bonding pads 11 and the first solder layer 21 (pillar bumps) to avoid metal diffusion between the bonding pads 11 and the first solder layer 21. However, the outmost layer of the under bump metallurgy (UBM) layer is gold (Au), therefore, Au embrittlement happens quite often on the pillar bumps made of solder.

### SUMMARY

The main objective of the present invention is to provide an IC chip with improved pillar bumps. A solder layer is formed over an UBM (Under Bump Metallurgy) layer of a chip to connect the pillar bumps. The pillar bumps are connected to the UBM layer via the solder layer. The solder layer has a melting point lower than that of the pillar bumps. When reflowing the solder layer, the pillar bumps can retain their pillar shapes and be connected to the UBM layer via the solder layer. Thus, the bonding strength and stress resistance of the pillar bumps can be effectively improved.

The secondary objective of the present invention is to provide an IC chip with improved pillar bumps. The solder layer is formed over the bonding pads of the IC chip for connecting the pillar bumps to an UBM layer or the bonding pads. The pillar bumps can be self-aligned with the corresponding bonding pads in fine pitch applications via the solder layer during reflow processes. Therefore the bonding strength of the pillar bumps is improved.

The IC chip with improved pillar bumps in accordance with the present invention comprises a chip, an UBM layer, a solder layer and a plurality of pillar bumps. The chip has an active surface and a back surface. The chip includes a passivation layer and a plurality of bonding pads on the active surface. The passivation layer has a plurality of openings exposing the bonding pads. The UBM layer is formed onto the bonding pads. Preferably, the UBM layer covers the bonding pads and the periphery of the openings of the passivation layer. The solder layer is formed over the UBM layer. The solder layer has a melting point lower than that of the pillar bumps so that the pillar bumps are connected to the UBM layer via the solder layer. When reflowing the solder layer, the pillar bumps can retain their pillar shapes and be connected to the UBM layer via the solder layer. Therefore the bonding strength and the metal wettability of the pillar bumps are improved.

### DESCRIPTION OF THE DRAWINGS

FIG. 1 is a cross-sectional view of a conventional IC chip with pillar bumps.

FIG. 2 is a cross-sectional view of an IC chip with improved pillar bumps in accordance with an embodiment of the present invention.

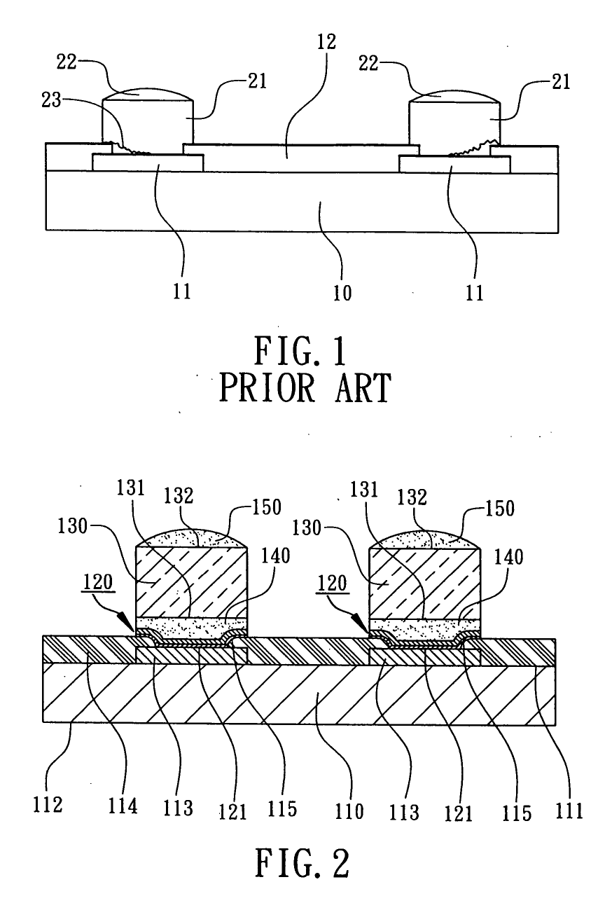

### DESCRIPTION OF THE PRESENT INVENTION

Referring to the drawings attached, the present invention will be described by means of the embodiments below.

Referring to FIG. 2, an IC chip with improved pillar bumps according to the present invention mainly comprises a chip 110, an UBM layer 120 (Under Bump Metallurgy), a plurality of pillar bumps 130, and a solder layer 140. The chip 110 has an active surface 111 and a back surface 112. The integrated circuits are fabricated on the active surface 111 of the chip 110, such as microprocessor, microcontroller, ASIC, or memories. The chip 110 includes a plurality of bonding pads 113 on the active surface 111 in matrix array, central array or peripheral array. The bonding pads 113 may be aluminum pads or copper pads. A passivation layer 114 is formed over the active surface 111 of the chip 110, and made of low K material such as PSG or PI. In this embodiment, the passivation layer 114 has a plurality of openings 115 to partially expose the bonding pads 113.

The UBM layer 120 is formed onto the bonding pads 113. The UBM layer 120 includes a barrier layer and a bonding layer, which may be selected consisting of Ti—Ni/V—Cu, Al—Ni/V—Cu, Ti—Cu, Cr—Cu and Cr—Cr/Cu—Cu. A metal layer comprising Ti, Ni, V, Cr can be used as the barrier layer of the UBM layer 120 to block metal diffusion between the bonding pads 113 and the pillar bumps 130. In this embodiment, the UBM layer 120 is formed onto the corresponding bonding pads 113 by means of sputtering or vapor deposition. The UBM layer 120 is further extended onto the passivation layer 114 and has a dimension larger than the openings 115 of the passivation layer 114 to cover the exposed bonding pads 113 and the periphery of the openings 115 of the passivation layers 114. The solder layer 140 is formed over the UBM layer 120 as a first reflowed adhesive layer. Preferably, the solder layer 140 has a thicker thickness than that of the UBM layer 120. The solder layer 140 is 63/37 lead-tin alloy, other low-lead solder or lead-free solder. The solder layer 140 has a melting point lower than that of the pillar bumps 130, preferably is lower than 200 C, so as to connect the pillar bumps 130 to the UBM layer 120.

The pillar bumps 130 are connected to the UBM layer 120 via the solder layer 140. Each pillar bump 130 has a bottom surface 131 and a top surface 132. The pillar bumps 130 retain their pillar shapes even reflowing the solder layer 140 so that the pillar bumps 130 can be connected to the UBM layer 120 via the solder layer 140. In this embodiment, the pillar bumps 130 are high lead bumps, such as 95/5 lead-tin alloy (Pb/Sn), and have a melting point at least 50° C. higher than that of the solder layer 140. The solder layer 140 is reflowed to connect the bottom surfaces 131 of the corresponding pillar bumps 130 to the UBM layer 120, preferably the bottom surfaces 131 are flat and has a dimension larger than that of the openings 115 of the passivation layer 114. The solder layer 140 covers the UBM layer 120 and has a proper thickness so that the pillar bumps 130 do not contact the UBM layer 120 nor the passivation layer 114. Alternatively, the pillar bumps 130 can be selected from the group consisting of copper pillars, gold pillars and conductive resin pillars. An arc solder 150, which material can be the same as the solder layer 140, is formed on the top surfaces 132 of the pillar bumps 130 as a second reflowed adhesive layer for outer electrical connection to a printed circuit board or a substrate. The arc solder 150 can be reflowed at the same time as the solder layer 140 is reflowed.

Because that the solder layer 140 is formed between the UBM layer 120 and the bottom surfaces 131 of the pillar bumps 130, therefore, the pillar bumps 130 can be self-aligned with the corresponding bonding pads 113 beneath the UBM layer 120 when the solder layer 140 is reflowed to reach its melting point. The solder layer 140 can connect the bottom surfaces 131 of the pillar bumps 130 to the UBM layer 120. However, the pillar bumps 130 still retain their pillar shapes during reflowing the solder layer 140. The solder layer 140 on the UBM layer 120 can be used for self-alignment of the pillar bumps 130 during flip-chip bonding or inner lead bonding processes. Therefore, the pillar bumps 130 have an excellent bonding strength and stress resistance with respect to the UBM layer 120. Furthermore, when a flip-chip bonding or inner lead bonding process is conducted by using the IC chip 110 with improved pillar bumps 130, the arc solder 150 on the pillar bumps 130 are used for bonding an outer electric printed circuit board or substrate. The solder layer 140 can be moderately melted to release the stress caused by CTE mismatch to effectively prevent crack on the bottom surfaces 131 of the pillar bumps 130.

Moreover, according to the IC chip with improved pillar bumps of the present invention, the solder layer 140 is not limited only to be formed over the UBM layer 120 but also can be directly formed over the bonding pads 113 on the active surface 111 of the chip 110 for connecting the pillar bumps 130 to the bonding pads 113. Preferably, the bonding pads 113 includes a barrier layer. The solder layer 140 is able to cover the exposed bonding pads 113 and the inwalls of the openings 115 of the passivation layer 114, and further fill the openings 115 of the passivation layer 114 in another embodiment (not shown in the figure). Accordingly, the pillar bumps 130 can be lifted up by the solder layer 140 without contacting the passivation layer 114 nor the bonding pads 113 so as to improve the bonding strength and stress resistance of the pillar bumps 130.

The above description of embodiments of this invention is intended to be illustrated and not limited. Other embodiments of this invention will be obvious to those skilled in the art in view of the above disclosure.

1. An IC chip with improved pillar bumps comprising:
a chip having an active surface and a back surface and including a plurality of bonding pads and a passivation layer, the passivation layer being formed over the active surface and having a plurality of openings exposing the bonding pads;
an UBM layer formed onto the bonding pads;
a solder layer formed over the UBM layer; and
a plurality of pillar bumps connected to the UBM layer via the solder layer;
wherein the solder layer has a melting point lower than that of the pillar bumps.

2. The IC chip in accordance with claim 1, wherein the pillar bumps are high lead bumps.

3. The IC chip in accordance with claim 1, wherein the solder layer is low-lead solder or lead-free solder.

4. The IC chip in accordance with claim 1, wherein the UBM layer includes at least a barrier layer.

5. The IC chip in accordance with claim 4, wherein the barrier layer is selected from the group comprising Ti, Ni, V, Cr.

6. The IC chip in accordance with claim 1, wherein the bonding pads are partially exposed out of the openings of the passivation layer, the UBM layer is larger than the openings to extend onto the passivation layer.

7. The IC chip in accordance with claim 1, wherein each pillar bump has a flat bottom surface, the solder layer is wet on the flat bottom surface.

8. The IC chip in accordance with claim 1, wherein the melting point of the solder layer is not higher than 200° C.

9. The IC chip in accordance with claim 1, wherein the melting point of the pillar bumps is at least 50° C. higher than that of the solder layer.

10. The IC chip in accordance with claim 1, wherein the pillar bumps are selected from the group consisting of copper pillars, gold pillars, and conductive resin pillars.

11. The IC chip in accordance with claim 1, further comprising an arc solder on the top surfaces of the pillar bumps.

12. The IC chip in accordance with claim 1, wherein the bottom surfaces of the pillar bumps are not smaller than the openings.

13. The IC chip in accordance with claim 1, wherein the pillar bumps are self-aligned with the corresponding bonding pads.

14. An IC chip comprising:
a chip having an active surface and a back surface and including a plurality of bonding pads and a passivation layer, the passivation layer being formed over the active surface and having a plurality of openings exposing the bonding pads;
a first reflowed adhesive layer formed over the bonding pads; and
a plurality of bumps formed on the first reflowed layer.

15. The IC chip in accordance with claim 14, further comprising a second reflowed adhesive layer on the bumps.

16. The IC chip in accordance with claim 15, wherein the bumps retain their shapes when the first and second reflowed adhesive layers are reflowed.

17. The IC chip in accordance with claim 16, wherein the bumps are pillar in shape.

18. The IC chip in accordance with claim 15, wherein the pillar bumps have a melting point higher than that of the first reflowed adhesive layer and the second reflowed adhesive layer.

19. The IC chip in accordance with claim 14, wherein the bonding pads are partially exposed out of the openings of the passivation layer, the first reflowed adhesive layer fills the openings.

20. The IC chip in accordance with claim 14, wherein the bumps are self-aligned with the corresponding bonding pads.

21. The IC chip in accordance with claim 2, wherein the solder layer is low-lead solder or lead-free solder.
